(19) United States
(12) Patent Application Publication
(10) Pub. No.: US 2012/0187498 A1
(43) Pub. Date: Jul. 26, 2012

(54) Field-Effect Transistor with Integrated TJBS Diode

(76) Inventors: Ning Qu, Reutlingen (DE); Alfred Goerlach, Kusterdingen (DE)

(21) Appl. No.: 13/388,738

(22) PCT Filed: Jun. 10, 2010
(86) PCT No.: PCT/EP2010/058166

§ 371 Date: Apr. 12, 2012

(30) Foreign Application Priority Data
Aug. 5, 2009 (DE) 10 2009 028 240.8

(51) Int. Cl. H01L 27/088

(52) U.S. Cl. 257/368; 257/E27.06

(57) ABSTRACT

A semiconductor component includes at least one MOS field-effect transistor and a trench junction barrier Schottky diode (TJBS) configured as a monolithically integrated structure. The breakdown voltages of the MOS field-effect transistor and of the trench junction barrier Schottky diode (TJBS) are selected such that the MOS field-effect transistor can be operated in breakdown mode.

### BACKGROUND OF THE INVENTION

1. Field of the Invention

The present invention relates to a semiconductor component, e.g., a power MOS field-effect transistor having an integrated trench junction barrier Schottky (TJBS) diode, which power semiconductor component can be used, for example, in synchronous rectifiers for generators in motor vehicles.

2. Description of Related Art

Power MOS field-effect transistors have been used for decades as fast switches for applications in power electronics. In addition to planar, double-diffused structures (DMOS), power MOSFETs having trench structures (trench MOS) are also used. However, in applications having very fast switching processes, in which current also briefly flows via the body diode of the MOSFET, e.g. in synchronous rectifiers, DC-DC converters, etc., on-state power losses and switching losses of the pn body diode have a disadvantageous effect. As a possible remedy, a parallel circuit of the MOSFET is proposed, e.g. with its integrated pn body diode and a Schottky diode.

Thus, from U.S. Pat. No. 5,111,253 combination of a DMOS and an integrated Schottky barrier diode (SBD) is known. In Schottky diodes, the advantage of low forward voltage and low turn-off losses has to be weighed against the disadvantage of a higher reverse current. In addition to the reverse current, caused in principle by the barrier of the metal-semiconductor transition, there is also a reverse voltage-dependent portion caused by the so-called barrier lowering (BL). In published U.S. Patent application US-2005/0199918, a combination of a trench MOS with an integrated trench MOS barrier Schottky diode (TMBS) is proposed. In this way, the disadvantageous BL effect can largely be suppressed.

FIG. 1 shows a simplified cross-section of a system of a trench MOS with an integrated MOS barrier Schottky diode (TMBS). On a highly n⁺-doped silicon substrate 1 there is situated an n-doped silicon layer 2 (epi layer) in which a large number of trenches 3 have been made. On the side walls and on the floor of the trenches there is situated a thin dielectric layer 4 made mostly of silicon dioxide. The interior of the trenches is filled with a conductive material 5, e.g. doped polysilicon. For the majority of the trenches, a p-doped layer (p-well) 6 is situated between the trenches.

Highly n⁺-doped regions 8 (source) and highly p⁺-doped regions 7 (for connecting the p-well) are made on the surface of this p-doped layer. The surface of the overall structure is coated with a suitable conductive layer 9, e.g. with Ti or titanium silicide. In the regions in which a contact exists with p⁺-doped or n⁺-doped layers 7 and 8, conductive layer 9 acts as an ohmic contact. In the regions between the trenches that are not embedded in a p-doped layer 6, conductive layer 9 acts as a Schottky contact with n-doped regions 2 situated under it. Over conductive layer 9 there is generally situated another thicker conductive metallic layer, or a layer system made up of a plurality of metallic layers. This metallic layer 10, acting as a source contact, can be an aluminum alloy, standard in silicon technology, having copper and/or silicon portions, or can be some other metallic system. On the rear side, there is applied a standard solderable metallic system 11, e.g. made up of a layer sequence of Cr, NiV, and Ag. Metallic system 11 acts as drain contact. Polysilicon layers 5 are galvanically connected to one another and to a gate contact (not shown).

Electrically, the Schottky diode is thus the regions in which metallic layer 9 contacts n-doped silicon 2, connected in parallel to the body diode of the MOSFET, i.e. p-doped layer 6 and n-doped layer 2. If reverse voltage is applied, space charge zones form between the trench structures adjacent to the Schottky contacts, and shield the electrical field from the actual Schottky contacts, i.e. transition 9-2. Due to the lower field at the Schottky contact, the BL effect is reduced, i.e. an increase in reverse current with increasing reverse voltage is prevented. Due to the lower forward voltage of the Schottky diode, the pn body diode is not operated in the forward direction. Therefore, Schottky diode 9-2 acts as an inverse diode of the MOSFET.

Because in a Schottky diode no stored charge of minority bearers has to be cleared out, in the ideal case only the capacitance of the space charge zone is to be charged. The high reverse current peaks that occur in a pn diode due to the clearing out do not occur. With the integration of a Schottky diode, the switching behavior of the MOSFET is improved, and switching time and switching losses are lower.

For many applications, it is advantageous to be able to operate the MOSFET also in avalanche breakdown mode. Voltage peaks can be limited by the body diode. As a result of the parasitic NPN transistor that is always present in MOSFETs, undesired destructive breakdowns of the NPN structure may occur. Therefore, this operation should in general not be permitted. In the case of the integrated TMBS diode, such operation is possible in principle, but is not recommended for reasons of quality, due to the charge bearer injection that then occurs into the MOS structure of the TMBS.

In published U.S. Patent application US 2006/0202264, it is proposed to additionally integrate so-called junction barrier Schottky diodes into a trench MOS. Junction barrier Schottky diodes are planar Schottky diodes in whose flat regions diffusion has taken place with a conductivity type opposite to that of the substrate doping, e.g. p-doped regions in an n-doped substrate. When a reverse voltage is applied, the space charge zones between the p-doped regions grow together and shield the electrical field to some extent from the Schottky contact. This reduces the BL effect somewhat, but the effect is significantly less than in a TMBS structure. With such a system, it is possible to operate the MOSFET in avalanche breakdown mode without the danger of triggering and destroying the parasitic NPN transistor.

### BRIEF SUMMARY OF THE INVENTION

With the power semiconductor component according to the present invention, in an advantageous manner the barrier lowering effect (BL effect) that occurs in conventional components is effectively suppressed. For this purpose, it is proposed to additionally integrate TJBS diodes (trench MOS barrier Schottky diodes) into a power MOSFET. The breakdown voltage of the TJBS structure can be selected to be larger or smaller than the breakdown voltage of the additionally present pn body diode. In the case in which the avalanche breakdown voltage (Z voltage) of the TJBS structure is smaller than the breakdown voltage of the NPN transistor or of the pn body diode, the component can even be operated at higher currents in breakdown mode.

### BRIEF DESCRIPTION OF THE DRAWINGS

FIG. 1 shows a schematic cross-section of part of a power trench MOS field-effect transistor having an integrated TMBS diode as known from the existing art.

FIG. 2 shows a schematic cross-section of part of a first system according to the present invention.

FIG. 3 shows a schematic cross-section of part of a second system according to the present invention.

FIG. 4 shows a schematic cross-section of part of a further system according to the present invention.

FIG. 5 shows a schematic cross-section of part of a further system according to the present invention having integrated TJBS structures.

### DETAILED DESCRIPTION OF THE INVENTION

FIG. 2 shows a schematic cross-sectional view of parts of a first exemplary embodiment of the present invention. This is a monolithically integrated structure containing an MOS field-effect transistor and a TJBS diode. On a highly n⁺-doped silicon substrate 1 there is situated an n-doped silicon layer, for example an epi layer 2, in which a large number of trenches 3 have been made. Most of the trenches are in turn provided on their side walls and floor with a thin dielectric layer 4, in most cases made of silicon dioxide. The interior of these trenches is again filled with a conductive material 5, e.g. doped polysilicon. Polysilicon layers 5 are galvanically connected to one another and to a gate contact (not shown).

Between these trenches there is situated a p-doped layer (p-well) 6. On the surface of this p-doped layer there are formed highly n⁺-doped regions 8 (source) and highly p⁺-doped regions 7, for the connection of the p-well. In some regions of the component, there is no p-doped layer (p-well) 6 between the trenches, but only n-doped epi layer 2. These trenches are also not provided with a silicon dioxide layer 4, but rather are filled with p-doped silicon or polysilicon 12.

The trenches are either completely filled, as shown in FIG. 2, or only the surface of the trench walls and floors may be covered. On the upper side, these p-doped regions may be doped with highly p⁺-doped silicon over their entire surface or may be only partially doped in order to achieve a better ohmic contacting with the metal or silicide 9 situated thereover. For reasons of clarity, this layer is not depicted in the Figures. The depth of the trenches is, in a (20-40) volt component, approximately 1-3 μm, and the distance between the trenches, the mesa region, is then typically less than 0.5 μm. Of course, the dimensions are not limited to these values. Thus, for example in higher-blocking MOSFETs, deeper trenches and broader mesa regions are preferably selected. The known p-doped layer (p-well) 6 is connected to each of the outermost trenches filled with p-doped material. However, in the segment up to the next trench, filled with silicon dioxide 4 and polysilicon 5, there are no highly n⁺-doped regions 8 and for the most part also no highly p⁺-doped regions 7.

At the points in the trenches that are filled with p-doped silicon, epi layer 2 is contacted with a Schottky metal 9, e.g. titanium silicide. Transition 9-2 forms the actual Schottky diode. When reverse voltage is applied, space charge zones are formed between the trench structures that are adjacent to the Schottky contacts and are filled with p-silicon, and shield the electrical field from the actual Schottky contacts (transition 9-2). Due to the lower field at the Schottky contact, the BL effect is reduced, i.e. an increase in reverse current with increasing reverse voltage is prevented.

Region I is a so-called trench junction barrier Schottky diode (TJBS). The doping of p-layer 12 is selected such that breakdown voltage UZ_TJBS between p-layer 12 and n-doped epi layer 2 (TJBS) is smaller than breakdown voltage UZ_SBD of Schottky diode 9-2. Standardly, the breakdown voltage is also smaller than the breakdown voltage of pn inverse diode 6-2, or the breakdown voltage of the parasitic NPN transistor formed from regions 8, (7, 6) and 2.

Analogous to a known system according to FIG. 1, a system as shown in FIG. 2 achieves an improved switching characteristic without the reverse current disadvantages of a simple Schottky diode. In contrast thereto, the system is also suitable for reliable voltage limiting. Over conductive layer 9, as in the case of FIG. 1, there is again in general situated a thicker conductive metallic layer, or a layer system made up of a plurality of metallic layers (source contact). On the rear side of the component, metallic system 11 acts as a drain contact. Polysilicon layers 5 are galvanically connected to one another and to a gate contact (not shown).

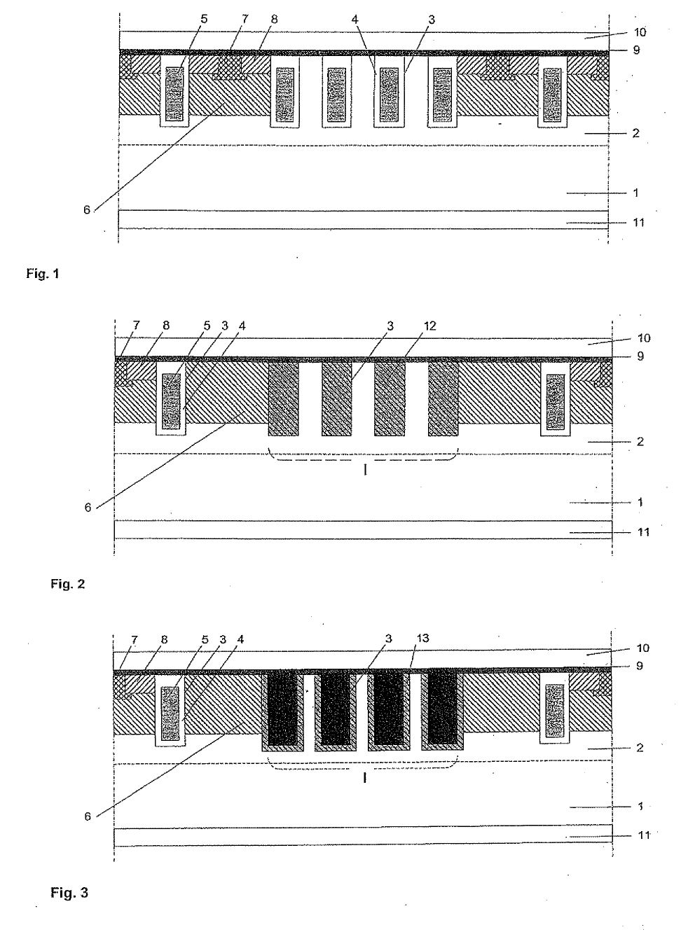

FIG. 3 shows a further exemplary embodiment of a system according to the present invention, having a monolithically integrated structure that includes an MOS field-effect transistor and a TJBS diode. The structure, function, and designation, with the exception of the inner region, are identical to those shown in the system according to the present invention shown in FIG. 2. Differing therefrom, the inner trenches, the trenches of the TJBS, are not filled with p-doped silicon or polysilicon, but rather are filled completely or partly with metal. A flat, highly p⁺-doped region 13, having a penetration depth of less than 100 nm, is connected to the side walls and to the floor of these trenches. This region is ohmically contacted with metallic layer 9.

Regions 13 can be produced e.g. using a diborane gas phase occupation with a subsequent diffusion or heating step, e.g. rapid thermal annealing RTP. The doping and the diffusion or heating step are selected such that the corresponding breakdown voltage UZ_TJBS is achieved. All further variants of the systems according to the present invention can optionally be realized with trenches 12 filled with p-doped silicon or polysilicon.

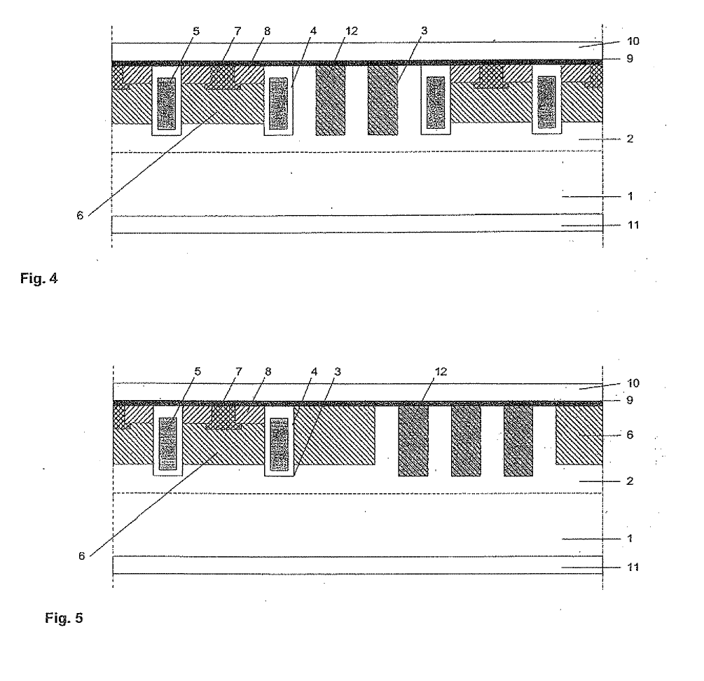

FIG. 4 shows a further variant of a system according to the present invention. Trenches with gate structure are situated opposite the trenches of the TJBS. If the MOSFET is to be operated in breakdown mode, the breakdown voltages are again set such that the TJBS has the lowest voltage of all the structures.

In the exemplary embodiments shown in FIGS. 2-4, the outermost trench structures of the TJBS either stand in contact with body region 6, as shown in FIGS. 2 and 3, or are situated opposite the MOS trench structures, as shown in FIG. 4. The trenches of the TJBS can however also be situated at a certain distance, as shown in FIG. 5, between p-doped body regions 6. Here, the TJBS structures can be situated inside the MOSFET chip or can be situated on the chip edge.

The semiconductor materials and dopings selected in the description of the solutions according to the present invention are presented as examples. In each case, instead of n-doping p-doping could be chosen, and instead of p-doping n-doping could be chosen.

1-22. (canceled)

23. A semiconductor component, comprising:
at least one MOS field-effect transistor; and
a trench junction barrier Schottky diode.

24. The semiconductor component as recited in claim 23, wherein the MOS field-effect transistor and the trench junction barrier Schottky diode are configured as a monolithically integrated structure.

25. The semiconductor component as recited in claim 24, wherein the breakdown voltages of the MOS field-effect transistor and of the trench junction barrier Schottky diode are selected such that the MOS field-effect transistor is able to operate in breakdown mode.

26. The semiconductor component as recited in claim 25, wherein the breakdown voltage of the trench junction barrier Schottky diode is selected as the smallest breakdown voltage such that the breakdown voltage of the trench junction barrier Schottky diode is smaller than (i) the breakdown voltage of a Schottky transition in the semiconductor component, (ii) the breakdown voltage of a pn inverse diode in the semiconductor component, and (iii) the breakdown voltage of a parasitic NPN transistor of the semiconductor component.

27. The semiconductor component as recited in claim 25, wherein:
an n-doped silicon layer is applied onto a highly n⁺-doped silicon substrate;
multiple trenches are provided in the n-doped silicon layer; and
for at least some of the trenches, (i) a thin dielectric layer is provided on at least one of side walls and floor, (ii) the interior of the trenches are filled with a layer of conductive material, and (iii) the layer of conductive material in the interior of the trenches is galvanically connected to one another and to a gate contact.

28. The semiconductor element as recited in claim 27, wherein the dielectric layer is made of silicon dioxide.

29. The semiconductor component as recited in claim 27, wherein the conductive material is doped polysilicon.

30. The semiconductor component as recited in claim 27, wherein:
a p-doped well is provided between at least a first pair of the trenches; and
in the surface of the p-doped well, highly n⁺-doped regions are provided as source and highly p⁺-doped regions are provided for the connection of the p-doped well.

31. The semiconductor component as recited in claim 30, wherein:
between at least a second pair of the trenches, (i) no p-doped well is provided, and (ii) only the n-doped silicon layer is provided; and
the second pair of trenches are filled with p-doped silicon, and the thin dielectric layer is not present in the second pair of trenches.

32. The semiconductor component as recited in claim 31, wherein:
in the region of the second pair of trenches filled with p-doped silicon, the n-doped silicon layer is contacted with a Schottky metal in the form of titanium silicide;
the transition region of the Schottky metal and the n-doped silicon layer forms a Schottky diode, so that when reverse voltage is applied, space charge zones are formed between the trench structures that are adjacent to Schottky contacts and are filled with p-silicon, thereby shielding the electrical field from the Schottky contacts at the transition region, and due to the lower field at the Schottky contact, reduce the barrier lowering effect, and an increase in reverse current with increasing reverse voltage is prevented.

33. The semiconductor component as recited in claim 32, wherein the overall structure including the second pair of trenches, the n-doped silicon layer, and the Schottky metal forms the trench junction barrier Schottky diode.

34. The semiconductor component as recited in claim 32, wherein a doping level of the p-doped silicon in the second pair of trenches is selected such that the breakdown voltage between the p-doped silicon and the n-doped silicon layer is smaller than the breakdown voltage of the Schottky diode.

35. The semiconductor component as recited in claim 34, wherein the breakdown voltage between the p-doped silicon and the n-doped silicon layer is also smaller than (i) the breakdown voltage of a pn inverse diode of the semiconductor component, and (ii) the breakdown voltage of a parasitic NPN transistor of the semiconductor component.

36. The semiconductor component as recited in claim 32, wherein:
on top of the Schottky metal, a second conductive metallic layer system thicker than the Schottky metal is provided and forms a source contact;
on an opposite side of the semiconductor component from the Schottky metal, a third metallic system is provided and forms a drain contact; and
the layer of conductive material in the interior of the trenches is a doped polysilicon layer which is galvanically connected to one another and to a gate contact for voltage limiting.

37. The semiconductor component as recited in claim 33, wherein the second pair of trenches forming the trench junction barrier Schottky diode are filled with metal, and wherein the side walls and floors of the second pair of trenches contain flat p-doped regions.

38. The semiconductor component as recited in claim 37, wherein at least one further pair of trenches in addition to the second pair of trenches are provided in the trench junction barrier Schottky diode, and the at least one further pair of trenches are filled completely with p-doped material, the upper portion of the at least one further pair of trenches being doped with p⁺ silicon.

39. The semiconductor component as recited in claim 33, wherein the second pair of trenches forming the trench junction barrier Schottky diode are filled with metal, and wherein the side walls and floors of the second pair of trenches contain flat, highly p⁺-doped regions having a penetration depth of less than 100 nm and ohmically contacted to the Schottky metal.

40. The semiconductor component as recited in claim 39, wherein the flat, highly p⁺-doped regions on the side walls and floors of the second pair of trenches are produced using a diborane gas phase occupation with a subsequent one of a diffusion step or a heating step.

41. The semiconductor component as recited in claim 33, wherein trenches with gate structure are situated opposite the trenches of the trench junction barrier Schottky diode, and when the MOS field-effect-transistor is to be operated in breakdown mode, the breakdown voltage of the trench junction barrier Schottky diode is selected as the smallest breakdown voltage such that the breakdown voltage of the trench junction barrier Schottky diode is smaller than (i) the breakdown voltage of a Schottky transition in the semiconductor component, (ii) the breakdown voltage of a pn inverse diode in the semiconductor component, and (iii) the breakdown voltage of a parasitic NPN transistor of the semiconductor component.

42. The semiconductor component as recited in claim 33, wherein the second pair of trenches of the trench junction barrier Schottky diode are situated at a predetermined distance from the p-doped well provided between the at least the first pair of the trenches, and wherein the trench junction barrier Schottky diode is situated in the interior of the MOS field-effect-transistor structure.
